(19) United States
(12) Patent Application Publication
(10) Pub. No.: US 2025/0266004 A1
(43) Pub. Date: Aug. 21, 2025

(54) DISPLAY DEVICE

(71) Applicant: LG Display Co., Ltd., Seoul (KR)

(72) Inventor: SangHyun LIM, Paju-si (KR)

(73) Assignee: LG Display Co., Ltd., Seoul (KR)

(21) Appl. No.: 19/047,291

(22) Filed: Feb. 6, 2025

(30) Foreign Application Priority Data
Feb. 20, 2024 (KR) 10-2024-0023933

(51) Int. Cl. G09G 3/3266; G09G 3/32

(52) U.S. Cl. CPC G09G 3/3266; G09G 3/32; G09G 2310/0267; G09G 2330/021

(57) ABSTRACT

A display device example can include a substrate having an active area and a non-active area, and a first gate driving circuit disposed on the substrate. The non-active area includes a first bending area between the active area and an area where the first gate driving circuit is disposed. The display device can further include an image display layer disposed on the substrate. The first gate driving circuit can be disposed to overlap with the image display layer on a rear surface of the substrate.

### CROSS REFERENCE TO RELATED APPLICATION

This application claims priority to Korean Patent Application No. 10-2024-0023933, filed in the Republic of Korea on Feb. 20, 2024, the entire contents of which is hereby expressly incorporated by reference into the present application.

### BACKGROUND

### Field

the present disclosure relates to a display device.

### Discussion of the Related Art

As the information society develops, there is an increasing demand for display devices for displaying images in various forms. Therefore, in recent years, there have been used various display devices such as liquid crystal displays and organic light emitting display devices.

A display device can include an active area in which an image is displayed, and a non-active area which is an area outside the active area. The non-active area can be referred to as a bezel area.

The description provided in the background section should not be assumed to be prior art merely because it is mentioned in or associated with the background section. The background section can include information that describes one or more aspects of the subject technology.

### SUMMARY OF THE DISCLOSURE

Example embodiments of the present disclosure can provide a display device capable of reducing the bezel area of the display device.

Example embodiments of the present disclosure can provide a display device capable of freely designing a gate driving circuit of the display device.

Example embodiments of the present disclosure can provide a display device including a substrate including an active area and a non-active area, and a first gate driving circuit disposed on the substrate, wherein the non-active area includes a first bending area between the active area and an area where the first gate driving circuit is disposed.

According to example embodiments of the present disclosure, it is possible to provide a display device capable of reducing the bezel area of the display device.

According to example embodiments of the present disclosure, it is possible to provide a display device capable of freely designing a gate driving circuit of the display device.

According to the example embodiments of the present disclosure, it is possible to provide a display device capable of low power consumption as a performance of a gate driving circuit is improved.

According to the example embodiments of the present disclosure, it is possible to provide a display device capable of bending a substrate of the display device.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a system configuration diagram of a display device according to example embodiments of the present disclosure.

FIG. 2 illustrates a display panel according to example embodiments of the present disclosure.

FIG. 3 is a cross-sectional view of a display panel according to example embodiments of the present disclosure.

FIG. 4 illustrates a substrate of a display panel according to example embodiments of the present disclosure.

FIG. 5 and FIG. 6 illustrate a substrate on which a gate driving circuit according to example embodiments of the present disclosure is disposed.

FIG. 7 is a cross-sectional view along line I-I′ of FIG. 6.

FIG. 8 illustrates a part of the substrate shown in FIG. 6 according to an example of the present disclosure.

FIG. 9, FIG. 10, FIG. 11, and FIG. 12 illustrate an area A1 of FIG. 6 according to examples of the present disclosure.

FIG. 13 and FIG. 14 illustrate signals output from a gate driving circuit according to example embodiments of the present disclosure.

FIG. 15 illustrates an equivalent circuit of a subpixel of a display panel according to example embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another.

Further, in the following description of examples or embodiments of the present invention, detailed descriptions of well-known functions and components incorporated herein will be omitted when it is determined that the description can make the subject matter in some embodiments of the present invention rather unclear. Names of the respective elements used in the following explanations can be selected only for convenience of writing the specification and can be thus different from those used in actual products.

The term “can” fully encompasses all the meanings and coverages of the term “may.” Further, the terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments can be provided so that this disclosure can be sufficiently thorough and complete to assist those skilled in the art to fully understand the scope of the present disclosure. Further, the present disclosure is only defined by scopes of claims.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

The shapes (e.g., sizes, lengths, widths, heights, thicknesses, locations, radii, diameters, and areas), ratios, angles, numbers, and the like, which are illustrated in the drawings to describe various example embodiments of the present disclosure are merely given by way of example. Therefore, the present disclosure is not limited to the illustrations in the drawings. Any implementation described herein as an “example” is not necessarily to be construed as preferred or advantageous over other implementations.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

The terms, such as “below,” “lower,” “above,” “upper” and the like, can be used herein to describe a relationship between elementitem(s) as illustrated in the drawings. It will be understood that the terms are spatially relative and based on the orientation depicted in the drawings.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, various example embodiments of the disclosure are described in detail with reference to the accompanying drawings. All the components of each display device or apparatus according to all embodiments of the present disclosure are operatively coupled and configured.

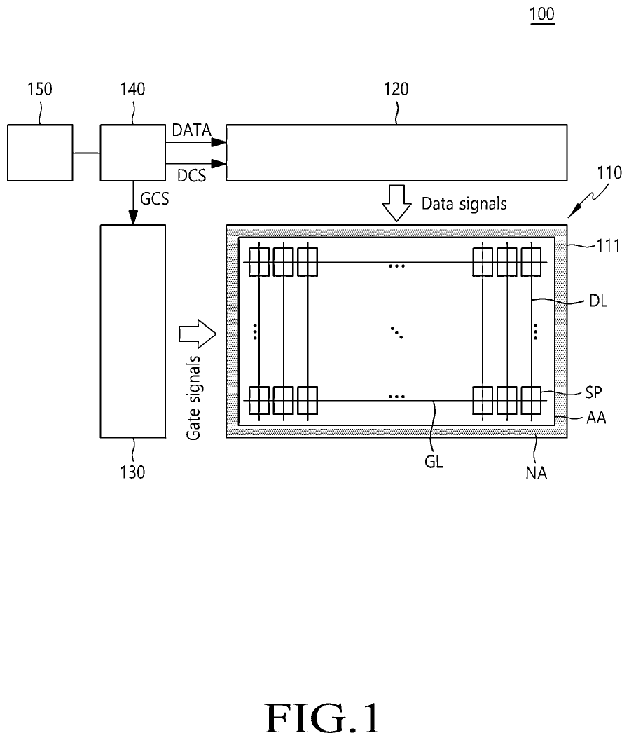

FIG. 1 is a system configuration diagram of a display device according to example embodiments of the present disclosure.

Referring to FIG. 1, a display device 100 according to example embodiments of the present disclosure can include a display panel 110 and a display driving circuit.

The display panel 110 and the display driving circuit can be components for displaying an image. The display panel 110 can include a substrate 111 and a plurality of subpixels SP disposed on the substrate 111.

The substrate 111 can include an active area AA (or display area) capable of displaying an image and a non-active area NA (or non-display area). The non-active area NA can be disposed on the outside of the active area AA. As an example, the non-active area NA can be extended from the active area AA. As an example, the non-active area NA can partially or fully surround the active area AA.

The active area AA can also be referred to as a display area. A plurality of subpixels SP for displaying an image can be disposed in the active area AA. The non-active area NA can also be referred to as a non-display area. There can be included a pad area on the display panel 110. As an example, there can be included a pad area positioned in a column direction from the active area AA, without being limited thereto.

In the display panel 110 according to the example embodiments of the present disclosure, the non-active area NA can be configured to be small. In the present specification, the non-active area NA can be a “bezel.” For example, the non-active area NA can include a first non-active area located outside the active area AA in the column direction, a second non-active area located outside the active area AA in a row direction, a third non-active area located outside the active area AA in the column direction opposite the first non-active area, and a fourth non-active area located outside the active area AA in the row direction opposite the second non-active area, but the embodiments of the present disclosure are not limited thereto. As an example, at least one of the first to fourth non-active areas can be omitted. As an example, at least one of the first to fourth non-active areas can be bent toward a rear side of the display panel 110 to be invisible from a front side of the display panel 110, without being limited thereto. Among the first to fourth non-active areas, the first non-active area can include a pad area to which a driving circuit is connected or bonded (or joined), without being limited thereto. Among the first to fourth non-active areas, the second to fourth non-active areas which do not include a pad area can have a very small size. As an example, the second to fourth non-active areas can have a size smaller than that of the first non-active area, without being limited thereto.

For another example, a boundary area between the active area AA and the non-active area NA can be bent so that the non-active area NA can be located below the active area AA. In this case, when an user views the display device 100 from the front, there can be little or no non-active area NA visible to the user, but embodiments of the present disclosure are not limited thereto.

Various types of signal lines for driving a plurality of subpixels SP can be disposed on the substrate 111 of the display panel 110.

The display device 100 according to example embodiments of the present disclosure can be a liquid crystal display device or the like, or can be a self-luminous display device in which the display panel 110 emits light by itself, without being limited thereto. When the display device 100 according to example embodiments of the present disclosure is a self-luminous display device, each of the plurality of subpixels SP can include a light emitting device.

For example, the display device 100 according to example embodiments of the present disclosure can be an organic light emitting display device in which a light emitting device is implemented as an organic light emitting diode (OLED). For another example, the display device 100 according to example embodiments of the present disclosure can be an inorganic light emitting display device in which the light emitting device is implemented as an inorganic-based light emitting diode. For another example, the display device 100 according to example embodiments of the present disclosure can be a quantum dot display device in which a light emitting device is implemented with quantum dots, which are semiconductor crystals emitting light by itself, however embodiments of the present disclosure are not limited thereto.

The structure of each of the plurality of subpixels SP can vary depending on the type of the display device 100. For example, if the display device 100 is a self-luminous display device with the subpixel SP emitting light by itself, each subpixel SP can include a self-luminous light emitting device, one or more transistors, and one or more capacitors, however embodiments of the present disclosure are not limited thereto.

For example, various types of signal lines can include a plurality of data lines DL supplying data signals (also called data voltages or image signals) and a plurality of gate lines GL for transmitting gate signals (also called scan signals).

For example, the plurality of data lines DL and the plurality of gate lines GL can cross each other. Each of the plurality of data lines DL can be arranged to extend in the column direction, and each of the plurality of gate lines GL can be arranged to extend in the row direction, without being limited thereto. According to example embodiments of the present disclosure, the column direction and the row direction can be relative directions. For example, the column direction can be a row direction or any other direction depending on the viewing point, and the row direction can be a column direction or any other direction depending on the viewing point. Hereinafter, for convenience of explanation, it will exemplified a case in which each of the plurality of data lines DL is arranged in a column direction, and each of the plurality of gate lines GL is arranged in a row direction, however embodiments of the present disclosure are not limited thereto. According to example embodiments of the present disclosure, an angle formed by the row direction and the column direction can be orthogonal (i.e., 90 degrees), or can be an angle different from the orthogonality Furthermore, in example embodiments of the present disclosure, the row direction can be described as a first direction, and the column direction can be described as a second direction.

The display driving circuit can be a circuit for driving the display panel 110. The display driving circuit can include a data driving circuit 120, a gate driving circuit 130, and a controller 140.

The data driving circuit 120 is a circuit for driving a plurality of data lines DL, and can output data signals to the plurality of data lines DL.

The data driving circuit 120 can receive image data in digital form from the controller 140 and convert the received image data into analog data signals to output the same to a plurality of data lines DL.

For example, the data driving circuit 120 can be connected to the display panel 110 using a tape automated bonding (TAB) method, or can be connected to the bonding pad of the display panel 110 using a chip-on-glass (COG) or chip-on-panel (COP) method, or can be implemented using a chip-on-film (COF) method and connected to the display panel 110.

The data driving circuit 120 can be connected to one side (e.g., the upper or lower side) of the display panel 110. Depending on the driving method, panel design method, etc., the data driving circuit 120 can be connected to both sides (e.g., upper and lower sides) of the display panel 110, or can be connected to two or more of the four sides of the display panel 110.

The data driving circuit 120 can be connected to the outside of the actice area AA of the display panel 110, but alternatively, it can be disposed in the actice area AA of the display panel 110.

The gate driving circuit 130 is a circuit for driving a plurality of gate lines GL, and can output gate signals to the plurality of gate lines GL.

The gate driving circuit 130 can receive a first gate voltage corresponding to the turn-on level voltage and a second gate voltage corresponding to the turn-off level voltage along with various gate driving control signals GCS, and can generate gate signals and supply the generated gate signals to the plurality of gate lines GL.

In the display device 100 according to the example embodiments of the present disclosure, the gate driving circuit 130 can be built into or embedded in the display panel 110 as a gate-in-panel (GIP) type, but the embodiments of the present disclosure are not limited thereto. As an example, the gate driving circuit 130 can be separately disposed in a separate panel and connected to one or more sides of the display panel 110 (e.g. the pad area), for example, in a tape automated bonding (TAB) method, a chip on glass (COG) method, a chip on panel (COP) method, or a chip on film (COF) method, without being limited thereto. If the gate driving circuit 130 is a gate-in-panel type, the gate driving circuit 130 can be formed on the substrate 111 of the display panel 110 during the manufacturing process of the display panel 110.

For example, the gate driving circuit 130 can be disposed in a non-active area NA of the display panel 110.

For another example, the gate driving circuit 130 can be disposed in an active area AA of the display panel 110. In this case, as an example, the gate driving circuit 130 can be disposed in a first partial area (e.g., a left area or a right area) within the active area AA. As another example, the gate driving circuit 130 can be disposed in a first partial area (e.g., a left area or a right area) within the active area AA and a second partial area (e.g., a right area or a left area) within the active area AA.

In the present disclosure, the gate driving circuit 130 built into the display panel 110 in the form of a gate-in-panel type can also be referred to as a “gate-in-panel circuit.”

The controller 140 can be a device for controlling the data driving circuit 120 and the gate driving circuit 130, and can control the driving timing for the plurality of data lines DL and the driving timing of the plurality of gate lines GL.

The controller 140 can supply a data driving control signal DCS to the data driving circuit 120 to control the data driving circuit 120, and can supply a gate driving control signal GCS to the gate driving circuit 130 to control the gate driving circuit 130.

The controller 140 can receive input image data from, for example, a host system 150 and supply image data DATA to the data driving circuit 120 based on the input image data.

The controller 140 can be implemented as a separate component from the data driving circuit 120, or can be integrated with the data driving circuit 120 and implemented as an integrated circuit.

The controller 140 can be a timing controller used in typical display technology, or can be a control device capable of further performing other control functions including a timing controller, or can be a control device different from the timing controller, or can be a control device other than a timing controller, or can be a circuit within the control device. The controller 140 can be implemented with various circuits or electronic components, such as an integrated circuit (IC), a field programmable gate array (FPGA), an application specific integrated circuit (ASIC), or Processor, however is not limited thereto.

The controller 140 can be mounted on a printed circuit board, a flexible printed circuit, etc., and can be electrically connected to the data driving circuit 120 and the gate driving circuit 130 through a printed circuit board, a flexible printed circuit, etc., without being limited thereto.

The controller 240 can transmit and receive signals with the data driving circuit 120 according to one or more predetermined interfaces. For example, the interface can include a low voltage differential signaling (LVDS) interface, an embedded clock point-point interface (EPI) interface, or a serial peripheral interface (SPI), without being limited thereto.

As an example, in order to provide not only an image display function but also a touch sensing function, the display device 100 according to example embodiments of the present disclosure can include a touch unit. The touch unit can include a touch sensor and a touch sensing circuit for detecting an occurrence of a touch by a touch object such as a finger or pen or detecting a touch position by sensing the touch sensor. As an example, the touch unit can be omitted depending on the design.

The touch sensing circuit can include a touch driving circuit for driving and sensing a touch sensor to generate and output touch sensing data, and a touch controller for detecting the occurrence of a touch or detecting the touch position using touch sensing data.

The touch sensor can include a plurality of touch electrodes. The touch sensor can further include a plurality of touch lines to electrically connect a plurality of touch electrodes and the touch driving circuit.

The touch sensor can exist outside the display panel 110 in the form of a touch panel or can exist inside the display panel 110. If the touch sensor exists outside the display panel 110 in the form of a touch panel, the touch sensor can be referred to as an external type. If the touch sensor is an external type, the touch panel and the display panel 110 can be manufactured separately and combined during the assembly process. As an example, the external touch panel can include a touch panel substrate and a plurality of touch electrodes on the touch panel substrate, without being limited thereto.

If the touch sensor exists inside the display panel 110, the touch sensor can be formed on the substrate along with signal lines and electrodes related to display driving during the manufacturing process of the display panel 110.

The touch driving circuit can supply a touch driving signal to at least one of the plurality of touch electrodes and generate touch sensing data by sensing at least one of the plurality of touch electrodes.

The touch sensing circuit can perform touch sensing using a self-capacitance sensing method or a mutual-capacitance sensing method.

If the touch sensing circuit performs touch sensing using a self-capacitance sensing method, the touch sensing circuit can perform touch sensing based on the capacitance between each touch electrode and a touch object (e.g., finger, pen, etc.). According to the self-capacitance sensing method, each of the plurality of touch electrodes can serve as a driving touch electrode and a sensing touch electrode. The touch driving circuit can drive all or part of the plurality of touch electrodes and sense all or part of the plurality of touch electrodes.

If the touch sensing circuit performs touch sensing using the mutual-capacitance sensing method, the touch sensing circuit can perform touch sensing based on the capacitance between touch electrodes. According to the mutual-capacitance sensing method, the plurality of touch electrodes can be divided into driving touch electrodes and sensing touch electrodes. The touch driving circuit can drive driving touch electrodes and sense sensing touch electrodes.

The touch driving circuit and the touch controller included in the touch sensing circuit can be implemented as separate devices or as one device. Additionally, the touch driving circuit and the data driving circuit can be implemented as separate devices or as one device.

The display device 100 can further include a power supply circuit which supplies various types of power to the display driving circuit and/or the touch sensing circuit.

The display device 100 according to example embodiments of the present disclosure can be a mobile terminal such as a smart phone or tablet, or a monitor or television of various sizes, but is not limited thereto, and can be a display of various types and sizes capable of displaying information or images. As an example, the display device 100 according to example embodiments of the present disclosure can be a vehicle, a building, a household appliances, a wearable device, etc., without being limited thereto.

The display device 100 according to example embodiments of the present disclosure can further include an electronic device such as a camera (e.g., image sensor) and/or a detection sensor, without being limited thereto. For example, the detection sensor can be a sensor for detecting an object or a human body by receiving light such as infrared, ultrasonic, or ultraviolet rays, without being limited thereto. As an example, at least one of the camera and the detection sensor can be omitted depending on the design.

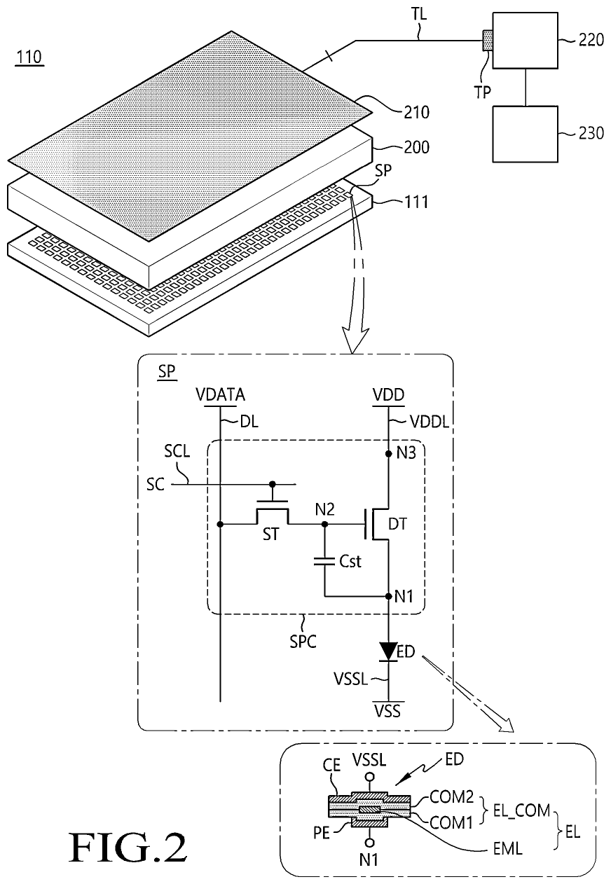

FIG. 2 illustrates a display panel 110 according to example embodiments of the present disclosure.

Referring to FIG. 2, the display panel 110 can include a substrate 111 on which a plurality of subpixels SP is disposed and an encapsulation layer 200 on the substrate 111. Here, the encapsulation layer 200 can also be referred to as an encapsulation substrate or an encapsulation portion.

When the display device 100 according to example embodiments of the present disclosure is a self-luminous display device, each of the plurality of subpixels SP can include a light emitting device ED and a subpixel circuit SPC for driving the light emitting device ED.

The subpixel circuit SPC can include a plurality of pixel driving transistors and at least one capacitor for driving the light emitting device ED. In the present disclosure, the subpixel circuit SPC can drive the light emitting device ED by supplying a driving current to the light emitting device ED at a predetermined timing. The light emitting device ED can be driven by a driving current and emit light.

The plurality of pixel driving transistors can include a driving transistor DT for driving the light emitting device ED, and a scan transistor ST which is turned on or off depending on the scan signal SC.

The driving transistor DT can supply driving current to the light emitting device ED.

The scan transistor ST can be configured to control the electrical state of a corresponding node in the subpixel circuit SPC or to control the state or operation of the driving transistor DT.

At least one capacitor can include a storage capacitor Cst to maintain a constant voltage during a certain time (e.g., the frame).

In order to drive the subpixel SP, a data signal VDATA which is an image signal, and a scan signal SC which is a gate signal can be applied to the subpixel SP. In addition, a common pixel driving voltage including a first driving voltage VDD and a second driving voltage VSS can be applied to the subpixel SP in order to drive the subpixel SP.

The light emitting device ED can include a pixel electrode PE, an intermediate layer EL, and a common electrode CE. The intermediate layer EL can be a layer disposed between the pixel electrode PE and the common electrode CE.

For example, the pixel electrode PE can be an electrode disposed in each subpixel SP, and the common electrode CE can be an electrode commonly disposed in a plurality of sub-pixels SP. For example, the pixel electrode PE can be an anode, and the common electrode CE can be a cathode. For another example, the pixel electrode PE can be a cathode, and the common electrode CE can be an anode. Hereinafter, for convenience of explanation, it will be exemplified a case where the pixel electrode PE is an anode and the common electrode CE is a cathode. Embodiments are not limited thereto. As an example, each of the pixel electrode PE and the common electrode CE can be separately disposed in each subpixel SP. As an example, the common electrode CE can be commonly disposed in at least some of a plurality of sub-pixels SP.

In the case that the light emitting device ED is an organic light emitting device, the intermediate layer EL can include an emission layer EML, a first common intermediate layer COM1 between the pixel electrode PE and the emission layer EML, and a second common intermediate layer COM2 between the emission layer EML and the common electrode CE. The first common intermediate layer COM1 and the second common intermediate layer COM2 can be collectively referred to as a common intermediate layer EL COM. As an example, at least one or both of the first common intermediate layer COM1 and the second common intermediate layer COM2 can be omitted depending on the design.

The emission layer EML can be disposed in each subpixel SP. The common intermediate layer EL COM can be commonly disposed across a plurality of subpixels SP.

The emission layer EML can be disposed in each emission area, and the common intermediate layer EL COM can be commonly disposed across a plurality of emission areas and non-emission areas. Embodiments are not limited thereto. As an example, the emission layer EML can be also commonly disposed across a plurality of subpixels SP or commonly disposed across a plurality of emission areas and non-emission areas, without being limited thereto.

For example, the first common intermediate layer COM1 can include a hole injection layer HIL and/or a hole transport layer HTL. The second common intermediate layer COM2 can include an electron transport layer ETL and/or an electron injection layer EIL, however embodiments of the present disclosure are not limited thereto.

The hole injection layer can inject holes from the pixelelectrode PE to the hole transport layer, the hole transport layer can transport holes to the emission EML, the electron injection layer can inject electrons from the common electrode CE to the electron transport layer, and the electron transport layer can transport electrons to the emission layer EML.

For example, the common electrode CE can be electrically connected to a base voltage line VSSL. A base voltage VSS, which is a type of common pixel driving voltage, can be applied to the common electrode CE through the base voltage line VSSL. The pixel electrode PE can be electrically connected directly or indirectly (e.g., via another one or more transistor) to a first node N1 of a driving transistor DT of each subpixel SP. In the present disclosure, “base voltage VSS” can also be referred to as “low-potential power supply voltage or low-potential voltage,” and “base voltage line VSSL” can also be referred to as “low-potential power supply voltage line or low-potential voltage line,” but embodiments of the present disclosure are not limited thereto.

Each light emitting device ED can be composed of overlapping parts of the pixel electrode PE, the intermediate layer EL and the common electrode CE. A predetermined emission area can be formed by each light emitting device ED. For example, the emission area of each light emitting device ED can include an area where the pixel electrode PE, the intermediate layer EL and the common electrode CE overlap.

For example, the light emitting device ED can be an organic light emitting diode (OLED), an inorganic light emitting diode, or a quantum dot light emitting device, without being limited thereto. For example, in the case that the light emitting device ED is an organic light emitting diode OLED, the intermediate layer EL in the light emitting device ED can include an organic intermediate layer EL containing an organic material, without being limited thereto.

The driving transistor DT can be a driving transistor for supplying driving current to the light emitting device ED. The driving transistor DT can be connected between a driving voltage line VDDL and the light emitting device ED.

The driving transistor DT can include a first node N1, a second node N2, and a third node N3. The first node N1 can be electrically connected to the light emitting device ED, the second node N2 can receive a data signal VDATA, and the third node N3 can receive a driving voltage VDD from the driving voltage line VDDL.

In the driving transistor DT, the second node N2 can be a gate node, the first node N1 can be a source node or a drain node, and the third node N3 can be a drain node or a source node. Hereinafter, for convenience of explanation, it will be described a case in which the second node N2 is a gate node, the first node N1 is a source node, and the third node N3 is a drain node in the driving transistor DT, but embodiments of the present disclosure are not limited thereto.

The scan transistor ST included in the subpixel circuit SPC can be a switching transistor for transmitting a data signal VDATA, which is an image signal, to the second node N2 which is the gate node of the driving transistor DT.

The scan transistor ST can be controlled on-off by the scan signal SC which is a gate signal applied through the scan line SCL as a type of gate line GL, and can control the electrical connection between the second node N2 of the driving transistor DT and the data line DL. The drain electrode or source electrode of the scan transistor ST can be electrically connected to the data line DL, and the source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed outside the driving transistor DT rather than a parasitic capacitor (e.g., Cgs, Cgd) as an internal capacitor which can exist between the first node N1 and the second node N2 of the driving transistor DT, but embodiments of the present disclosure are not limited thereto.

Each of the driving transistor DT and the scan transistor ST can be an n-type transistor or a p-type transistor. As an example, the driving transistor DT and the scan transistor ST can be of the same type or different types.

The display panel 110 can have a top emission structure, a bottom emission structure, or a dual emission structure.

If the display panel 110 has a top emission structure, as an example, at least a portion of the subpixel circuit SPC can overlap with at least a portion of the light emitting device ED in the vertical direction. Accordingly, the size of emission area can be increased and the aperture ratio can also be increased. Embodiments are not limited thereto. As an example, even if the display panel 110 has a top emission structure, the subpixel circuit SPC may not overlap with the light emitting device ED in the vertical direction.

If the display panel 110 has a bottom emission structure, the subpixel circuit SPC may not overlap with the light emitting device ED in the vertical direction, without being limited thereto.

The subpixel circuit SPC can have 2T-1C structure including two transistors T1 and T2 and one capacitor Cst. In some case, the subpixel circuit SPC can further include one or more transistors or one or more capacitors, but embodiments of the present disclosure are not limited thereto.

For example, the subpixel circuit SPC can have a 8T-1C structure including eight transistors and a single capacitor. For another example, the subpixel circuit SPC can have a 6T-2C structure including six transistors and two capacitors. For another example, the subpixel circuit SPC can have a 7T-1C structure including seven transistors and one capacitor, but embodiments of the present disclosure are not limited thereto.

Depending on the structure of the subpixel circuit SPC, there can vary the type and number of gate lines and/or gate signal supplied to the subpixel SP. In addition, depending on the structure of the subpixel circuit SPC, there can vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 can be disposed on the display panel 110 to reduce or prevent oxygen from penetrating into the circuit elements (particularly, the light emitting device ED). The encapsulation layer 200 can be configured in various shapes to reduce or prevent the light emitting device ED from coming into contact with moisture or oxygen. For example, the encapsulation layer 200 can be composed of two or more layers in which organic films and inorganic films are alternately laminated, but the embodiments of the present disclosure are not limited thereto. As an example, the encapsulation layer 200 can be composed of one single layer of an organic films or an inorganic films.

The display device 100 according to the example embodiments of the present disclosure can further include a touch sensor layer 210 including a plurality of sensor electrodes, a touch driving circuit 220 configured to sense the plurality of sensor electrodes, and a touch controller 230 configured to determine the presence or absence of a touch or touch coordinates by using the sensing result (i.e., touch sensing data) of the touch driving circuit 220. The touch sensor layer 210 can be a touch unit, but the embodiments of the present disclosure are not limited thereto.

The touch sensor layer 210 can be built or embedded into the display panel 110. For example, the touch sensor layer 210 can be disposed on an encapsulation layer 200 within the display panel 110.

The display panel 110 can further include a plurality of touch pads TP to which the touch driving circuit 220 is electrically connected, and a plurality of touch routing lines TL for electrically connecting a plurality of sensor electrodes included in the touch sensor layer 210 to the plurality of touch pads TP to which the touch driving circuit 220 is connected, but the embodiments of the present disclosure are not limited thereto.

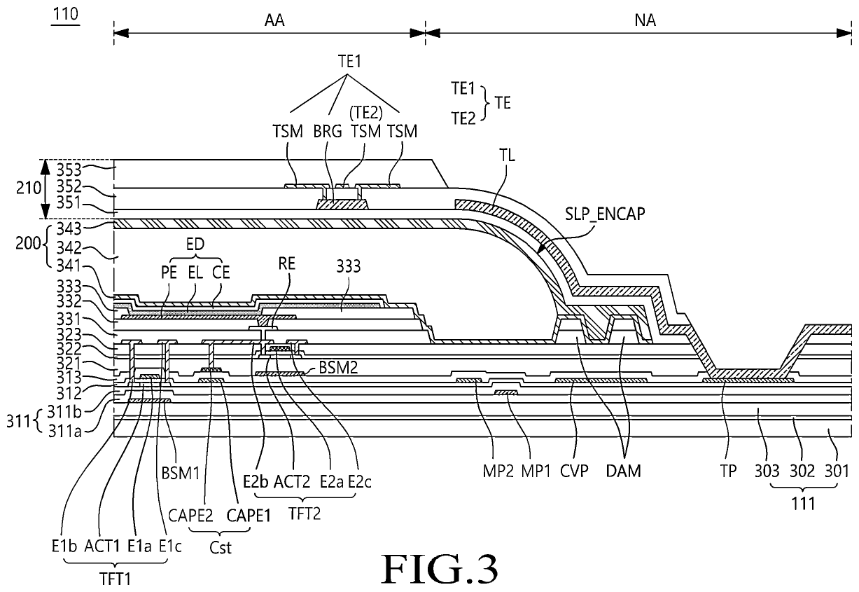

FIG. 3 is a cross-sectional view of a display panel 110 according to example embodiments of the present disclosure.

Referring to FIG. 3, the display panel 110 according to the example embodiments of the present disclosure can include a transistor formation portion, a light emitting device formation portion, and an encapsulation portion in terms of a vertical structure.

The substrate 111 can be a single layer or a multilayer. If the substrate 111 is a multilayer, the substrate 111 can include a first substrate 301, a substrate intermediate layer 302, and a second substrate 303. The substrate intermediate layer 302 can be located between the first substrate 301 and the second substrate 303. For example, each of the first substrate 301 and the second substrate 303 can be a polyimide (PI) layer. The substrate intermediate layer 302 can be an inorganic insulating layer. The substrate intermediate layer 302 can block the charge from affecting the transistors disposed on the second substrate 303 through the second substrate 303, which is a polyimide layer, when the charge is charged on the first substrate 301 which is a polyimide layer. Embodiments are not limited thereto. As an example, if the substrate 111 is a multilayer, the substrate 111 can include two or more layers of inorganic or organic materials other than polyimide.

In addition, the substrate intermediate layer 302 can block or reduce moisture components from penetrating upward through the first substrate 301. For example, the substrate intermediate layer 302 can be formed of a single layer of silicon nitride (SiNx) or silicon oxide (Siox), or a multilayer thereof, and can also be formed of a double layer of silicon dioxide (SiO2) and silicon nitride (SiNx), but is not limited thereto.

The transistor formation portion can include the substrate 111, a plurality of insulating layers 311, 312, 313, 321, 322 and 323 on the substrate 111, a plurality of transistors TFT1 and TFT2, a storage capacitor Cst, and a plurality of electrodes or signal lines.

The transistors TFT1 and TFT2 included in the transistor formation portion can include a first transistor TFT1 and a second transistor TFT2. Embodiments are not limited thereto. As an example, one or more additional transistors can be further included.

The first transistor TFT1 can include a first active layer ACT1, a first electrode E1a, a second electrode E1b, and a third electrode E1c. The first active layer ACT1 can be a first semiconductor layer, but the embodiments of the present disclosure are not limited thereto. For example, the first active layer ACT1 can be composed of oxide semiconductor, amorphous silicon, polysilicon, low-temperature polysilicon (LTPS), compound semiconductor, organic semiconductor, etc., but the embodiments of the present disclosure are not limited thereto. The first transistor TFT1 can be implemented as a p-channel transistor or an n-channel transistor, but the embodiments of the present disclosure are not limited thereto.

The first electrode E1a can be a gate electrode, the second electrode E1b can be a source electrode or a drain electrode, and the third electrode E1c can be a drain electrode or a source electrode. Hereinafter, for convenience of explanation, the first electrode E1a is referred to as a first gate electrode E1a, the second electrode E1b is referred to as a first source electrode E1b, and the third electrode E1c is referred to as a first drain electrode E1c. However, the embodiments of the present disclosure are not limited thereto.

The second transistor TFT2 can include a second active layer ACT2, a fourth electrode E2a, a fifth electrode E2b, and a sixth electrode E2c. The second active layer ACT2 can be a second semiconductor layer, but embodiments of the present disclosure are not limited thereto. For example, the second active layer ACT2 can be composed of an oxide semiconductor, amorphous silicon, polysilicon, low-temperature polysilicon (LTPS), compound semiconductor, organic semiconductor, etc., but embodiments of the present disclosure are not limited thereto. The second transistor TFT2 can be implemented as a p-channel transistor or an n-channel transistor, but embodiments of the present disclosure are not limited thereto. Although it is illustrated that the first transistor TFT1 and the second transistor TFT2 are disposed on different layers, embodiments are not limited thereto. As an example, the first transistor TFT1 and the second transistor TFT2 can at least partially overlap each other in a horizontal direction, without bring limited thereto. As an example, the first transistor TFT1 and the second transistor TFT2 can be disposed on the same layer, and have the same configuration, without being limited thereto.

For example, one of the first transistor TFT1 and the second transistor TFT2 can be configured with an oxide semiconductor as an active layer. For another example, one of the first transistor TFT1 and the second transistor TFT2 can be configured with low-temperature polysilicon as an active layer. For another example, the first transistor TFT1 and the second transistor TFT2 can be configured with an oxide semiconductor as an active layer. For another example, the first transistor TFT1 and the second transistor TFT2 can be configured with low-temperature polysilicon as an active layer. For another example, a driving transistor DT among the first transistor TFT1 and the second transistor TFT2 can be configured with an oxide semiconductor as an active layer, and a scan transistor ST can be configured with low-temperature polysilicon as an active layer. For another example, among the first transistor TFT1 and the second transistor TFT2, the driving transistor DT can be configured with low-temperature polysilicon as an active layer, and the scan transistor ST can be configured with an oxide semiconductor as an active layer. For another example, the transistor included in the gate driving circuit 130 of the gate-in-panel (GIP) type can be configured with an oxide semiconductor or low-temperature polysilicon as an active layer. For another example, all the transistors configured on the substrate 111 and the transistor included in the gate driving circuit 130 of the gate-in-panel (GIP) type can be configured with an oxide semiconductor as an active layer, or a low-temperature polysilicon as an active layer, without being limited thereto.

The fourth electrode E2a can be a gate electrode, the fifth electrode E2b can be a source electrode or a drain electrode, and the sixth electrode E2c can be a drain electrode or a source electrode. Hereinafter, for convenience of explanation, the fourth electrode E2a is also referred to as a second gate electrode E2a, the fifth electrode E2b is also referred to as a second source electrode E2b, and the sixth electrode E2c is also referred to as a second drain electrode E2c. However, the embodiments of the present disclosure are not limited thereto.

As an example, the second active layer ACT2 of the second transistor TFT2 can be located higher from the substrate 111 than the first active layer ACT1 of the first transistor TFT1, without being limited thereto. As an example, the second active layer ACT2 of the second transistor TFT2 can be located lower than the first active layer ACT1 of the first transistor TFT1, or can be disposed on the same layer as the first active layer ACT1 of the first transistor TFT1.

A first buffer layer 311 can be disposed under the first active layer ACT1 of the first transistor TFT1, and a second buffer layer 321 can be disposed under the second active layer ACT2 of the second transistor TFT2. For example, the first active layer ACT1 of the first transistor TFT1 can be located on the first buffer layer 311, and the second active layer ACT2 of the second transistor TFT2 can be positioned on the second buffer layer 321. The second buffer layer 321 can be located higher than the first buffer layer 311.

The storage capacitor Cst can be disposed with various metal layers within the display panel 110, for example, the storage capacitor Cst can include a first capacitor electrode CAPE1 and a second capacitor electrode CAPE2, without being limited thereto. As an example, the storage capacitor Cst can include more than two capacitor electrodes and/or can be disposed on a different layer.

The light emitting device formation portion can include a plurality of light emitting devices ED disposed on at least one planarization layer 331 and 332. Each of the plurality of light emitting devices ED can include a pixel electrode PE, an intermediate layer EL, and a common electrode CE.

The encapsulation portion can include an encapsulation layer 200 on the plurality of light emitting devices ED. The encapsulation layer 200 can be a single layer or a multilayer. In addition to the encapsulation layer 200, the encapsulation portion can further include a dam DAM.

Hereinafter, it will be described in more detail a vertical structure of the display panel 110 according to example embodiments of the present disclosure with reference to FIG. 3.

Referring to FIG. 3, a first buffer layer 311 can be disposed on a substrate 111. The first buffer layer 311 can be a single layer or a multilayer. If the first buffer layer 311 is a multilayer, the first buffer layer 311 can include a first-1 buffer layer 311a and a first-2 buffer layer 311b, or can include three or more layers.

The first active layer ACT of the first transistor TFT1 can be disposed on the first buffer layer 311. The first active layer ACT1 can include a channel region where a channel is formed, a source connection region on one side of the channel region, and a drain connection region on the other side of the channel region.

A first gate insulating layer 312 can be disposed on the first active layer ACT of the first transistor TFT1. The first gate electrode E1a of the first transistor TFT1 can be disposed on the first gate insulating layer 312. A second insulating layer 313 can be disposed on the first gate electrode E1a of the first thin film transistor TFT1. The first gate insulating layer 312 can be a gate insulating layer, but embodiments of the present disclosure are not limited thereto. The second insulating layer 313 can be an interlayer insulating layer, but embodiments of the present disclosure are not limited thereto.

A second buffer layer 321 can be disposed on the second insulating layer 313. Embodiments are not limited thereto. As an example, the second buffer layer 321 can be omitted depending on the design.

The second active layer ACT2 of the second transistor TFT2 can be disposed on the second buffer layer 321. The second active layer ACT2 can include a channel region in which a channel is formed, a source connection region on one side of the channel region, and a drain connection region on the other side of the channel region.

A third gate insulating layer 322 can be disposed on the second active layer ACT2 of the second transistor TFT2. A fourth insulating layer 323 can be disposed on the second gate electrode E2a of the second thin film transistor TFT2. The third gate insulating layer 322 can be a gate insulating layer, but the embodiments of the present disclosure are not limited thereto. The fourth insulating layer 323 can be an interlayer insulating layer, but the embodiments of the present disclosure are not limited thereto.

The first source electrode E1b and the first drain electrode E1c of the first thin film transistor TFT1 and the second source electrode E2b and the second drain electrode E2c of the second thin film transistor TFT2 can be disposed on the fourth insulating layer 323, without being limited thereto. As an example, the first source electrode E1b and the first drain electrode E1c can be disposed on any layer above the first active layer ACT1, without being limited thereto.

The first source electrode E1b and the first drain electrode E1c of the first thin film transistor TFT1 can be connected to the source connection region and the drain connection region of the first active layer ACT1 through the holes of the fourth insulating layer 323, the third insulating layer 322, the second buffer layer 321, the second insulating layer 313, and the first gate insulating layer 312, respectively.

The second source electrode E2b and the second drain electrode E2c of the second thin film transistor TFT2 can be connected to the source connection region and the drain connection region of the second active layer ACT2, through the holes of the fourth insulating layer 323 and the third gate insulating layer 322, respectively.

The first source electrode E1b and the first drain electrode E1c of the first transistor TFT1, and the second source electrode E2b and the second drain electrode E2c of the second transistor TFT2 can include a first metal, and can be disposed in a first metal layer. Here, the first metal and the first metal layer can be referred to as a first source-drain metal and a first source-drain metal layer. Embodiments are not limited thereto. As an example, the second source electrode E2b and the second drain electrode E2c can include other conductive materials other than metal, and/or can include the same conductive material or different conductive materials.

As an example, the storage capacitor Cst can be formed by the first capacitor electrode CAPE1 and the second capacitor electrode CAPE2. In some cases, the storage capacitor Cst can be formed by three or more capacitor electrodes, and can be in the form of two or more capacitors connected in parallel, but embodiments of the present disclosure are not limited thereto.

Each of the first capacitor electrode CAPE1 and the second capacitor electrode CAPE2 can be disposed on a plurality of metal layers disposed within the display panel 110.

For example, the first capacitor electrode CAPE1 can include the same material (e.g., metal material) as the first gate electrode E1a of the first transistor TFT1 on the first gate insulating layer 312, and can be disposed on the same layer as the first gate electrode E1a, without being limited thereto. As an example, the first capacitor electrode CAPE1 can be separated from the first gate electrode E1a, without being limited thereto.

For example, the second capacitor electrode CAPE2 can be disposed on the second insulating layer 313, without being limited thereto.

The second source electrode E2b of the second transistor TFT2 can be electrically connected to the second capacitor electrode CAPE2 through a hole of the fourth insulating layer 323, the third gate insulating layer 322, and the second buffer layer 321, without being limited thereto.

For example, the first transistor TFT1 can be the scan transistor ST of FIG. 2, and the second transistor TFT2 can be the driving transistor DT of FIG. 2. As long as the scan transistor ST, the driving transistor DT and the storage capacitor Cst of FIG. 2 could be implemented, the number of insulating layers, semiconductor layers and conductive layers (e.g., metal layers), and the positions and connection relationship thereof could be variously changed.

The transistor formation portion can further include a plurality of metal layers MP1 and MP2. For example, a first metal layer MP1 can be disposed between the first-1 buffer layer 311a and the first-2 buffer layer 311b included in the first buffer layer 311, without being limited thereto. A second metal layer MP2 can be disposed on the same layer as the first gate electrode E1a of the first transistor TFT1, without being limited thereto. As an example, the second metal layer MP2 can be disposed on the same layer as the first gate electrode E1a, but embodiments of the present disclosure are not limited thereto. The first metal layer MP1 can be a first metal pattern, and the second metal layer MP2 can be a second metal pattern, but the embodiments of the present disclosure are not limited thereto.

Each of the first metal layer MP1 and the second metal layer MP2 can be disposed in the active area AA and/or the non-active area NA.

The transistor formation portion can further include a first shield metal BSM1 disposed on the substrate 111. The first shield metal BSM1 can overlap the first active layer ACT1 of the first transistor TFT1. The first shield metal BSM1 can be disposed below the first active layer ACT1 of the first transistor TFT1. For example, the first shield metal BSM1 can be disposed between the substrate 111 and the first buffer layer 311, or can be disposed between the first-1 buffer layer 311a and the first-2 buffer layer 311b, but the embodiments of the present disclosure are not limited thereto.

The transistor formation portion can further include a second shield metal BSM2 disposed on the substrate 111. The second shield metal BSM2 can overlap with the second active layer ACT2 of the second transistor TFT2. The second shield metal BSM2 can be disposed below the second active layer ACT2 of the second transistor TFT2.

For example, the second shield metal BSM2 can be disposed in a metal layer between the second insulating layer 313 and the second buffer layer 321. The second shield metal BSM2 can be disposed on the same layer layer as the second capacitor electrode CAPE2, but the embodiments of the present disclosure are not limited thereto.

For another example, the second shield metal BSM2 can be disposed on the same layer as the first gate electrode E1a of the first transistor TFT1, but the embodiments of the present disclosure are not limited thereto. As an example, at least one or both of the first shield metal BSM1 and the second shield metal BSM2 can be omitted depending on the design.

The transistor formation portion can further include a common driving voltage layer CVP to which a common driving voltage is applied. For example, the common driving voltage applied to the common driving voltage layer CVP can be also referred to as a power signal, and can be a driving voltage VDD or a base voltage VSS, or a voltage other than the driving voltage VDD and the base voltage VSS. but the embodiments of the present disclosure are not limited thereto. The driving voltage VDD can also be referred to as a high-potential power voltage (or high-potential power signal), and the base voltage VSS can also be referred to as a low-potential power voltage (or low-potential power signal).

The common driving voltage layer CVP can be disposed in the active area AA and/or the non-active area NA.

At least one planarization layer can be disposed on the first transistor TFT1 and the second transistor TFT2. In the example of FIG. 3, two planarization layers 331 and 332 are disposed on the first transistor TFT1 and the second transistor TFT2, but the embodiments of the present disclosure are not limited thereto. In some cases, three or more planarization layers can be disposed on the first transistor TFT1 and the second transistor TFT2, but the embodiments of the present disclosure are not limited thereto.

A first planarization layer 331 can be disposed on the first source electrode E1b and the first drain electrode E1c of the first transistor TFT1 and the second source electrode E2b and the second drain electrode E2c of the second transistor TFT2. For example, the first planarization layer 331 can be disposed so as to cover both the first transistor TFT1 and the second transistor TFT2. For example, the first planarization layer 331 can be disposed to cover both the first thin film transistor TFT1 and the second thin film transistor TFT2.

A relay electrode RE can be disposed on the first planarization layer 331. The relay electrode RE can electrically connect the second source electrode E2b of the second transistor TFT2 and the pixel electrode PE. Embodiments are not limited thereto. As an example, the relay electrode RE can be omitted depending on the design. As an example, the second source electrode E2b of the second transistor TFT2 can be directly connected to the pixel electrode PE.

The relay electrode RE can be electrically connected to the second source electrode E2b of the second transistor TFT2 through a hole of the first planarization layer 331. The second source electrode E2b of the second transistor TFT2 can be electrically connected to the second capacitor electrode CAPE2 of the storage capacitor Cst.

The relay electrode RE can be disposed within a second metal layer on the first planarization layer 331, and can include a second metal. The second metal and the second metal layer can be referred to as a second source-drain metal and a second source-drain metal layer, but the embodiments of the present disclosure are not limited thereto.

A second planarization layer 332 can be disposed on the relay electrode RE.

A light emitting device formation portion can be disposed on the second planarization layer 332. The light emitting device ED can be formed on the second planarization layer 332. The light emitting device ED can include a pixel electrode PE, an intermediate layer EL, and a common electrode CE, but the embodiments of the present disclosure are not limited thereto. The emission area of the light emitting device ED can be formed in an area where the pixel electrode PE, the intermediate layer EL, and the common electrode CE overlap and contact each other.

The pixel electrode PE can be disposed on the second planarization layer 332. The pixel electrode PE can be electrically connected to the relay electrode RE through a hole of the second planarization layer 332.

A bank 333 can be disposed on the pixel electrode PE. An opening of the bank 333 can expose a portion of the pixel electrode PE to form an emission area. For example, the opening of the bank 333 can overlap with a portion of the pixel electrode PE. The bank 333 can be composed of a material including a black pigment or the like, or an organic material such as a benzocyclobutene resin, a polyimide resin, an acrylic resin, or a photosensitive polymer, but the embodiments of the present disclosure are not limited thereto. If the bank 333 is composed of a material including a black pigment or a black dye, the bank can be a black bank. If the bank 333 is composed of a material including a black pigment or a black dye, it is possible to block light from the outside or light reflected from the outside, thereby further improving the luminance of the display device.

The intermediate layer EL of the light emitting device ED can be disposed on a portion of the pixel electrode PE and the bank 333. The common electrode CE can be disposed on the intermediate layer EL.

The encapsulation portion can be disposed on the light emitting device formation portion, and can be located on the common electrode CE. The encapsulation portion can include a encapsulation layer 200 formed on the common electrode CE.

The encapsulation layer 200 can reduce or prevent moisture or oxygen from penetrating into the light emitting device ED. For example, the encapsulation layer 200 can reduce or prevent moisture or oxygen from penetrating into an organic material included in the intermediate layer EL of the light emitting device ED. Here, the encapsulation layer 200 can be composed of a single layer or a multilayer, but the embodiments of the present disclosure are not limited thereto.

As an example, the encapsulation layer 200 can include a first encapsulation layer 341, a second encapsulation layer 342, and a third encapsulation layer 343, but the embodiments of the present disclosure are not limited thereto. For example, the first encapsulation layer 341 and the third encapsulation layer 343 can include an inorganic layer, and the second encapsulation layer 342 can include an organic layer, but the embodiments of the present disclosure are not limited thereto.

The display panel 110 according to example embodiments of the present disclosure can also include a touch sensor. In this case, the display panel 110 according to example embodiments of the present disclosure can include a touch sensor layer 210 formed on an encapsulation layer 200. The touch sensor layer 210 can be a touch portion or a touch unit, but the embodiments of the present disclosure are not limited thereto.

The touch sensor layer 210 can include a plurality of touch electrodes TE. In order to form a plurality of touch electrodes TE, the touch sensor layer 210 can include a sensor metal TSM and a bridge metal BRG. In the example embodiments of the present disclosure, the sensor metal TSM can be also referred to as a sensor metal layer TSM, and the bridge metal BRG can be also referred to as a bridge metal layer BRG.

The touch sensor layer 210 can further include insulating layers such as a buffer layer 351 on the encapsulation layer 200, an insulating layer 352 on the buffer layer 351, and a protective layer 353 on the insulating layer 352, but the embodiments of the present disclosure are not limited thereto. Here, the buffer layer 351 can be omitted.

As an example, the bridge metal BRG can be disposed between the buffer layer 351 and the insulating layer 352. The sensor metal TSM can be disposed between the insulating layer 352 and the protective layer 353. Embodiments are not limited thereto. As an example, the bridge metal BRG can be disposed between the insulating layer 352 and the protective layer 353, and the sensor metal TSM can be disposed between the buffer layer 351 and the insulating layer 352.

Each of the plurality of touch electrodes TE can be composed of the sensor metal TSM. Each of the plurality of touch electrodes TE can be a mesh-type electrode having a plurality of openings, or can be a block-type electrode, but the embodiments of the present disclosure are not limited thereto.

The plurality of touch electrodes TE can include a first touch electrode TE1 and a second touch electrode TE2. The sensor metal TSM included in the first touch electrode TEL can be electrically connected through the bridge metal BRG. For example, sensor metals TSM spaced apart from each other can be electrically connected by the bridge metal BRG to form one first touch electrode TE1.

The bridge metal BRG can be disposed on the buffer layer 351. The insulating layer 352 can be disposed on the bridge layers BRG. The sensor metal TSM can be disposed on the insulating layer 352. A portion of the sensor metal TSM can be connected to the corresponding bridge metal BRG through a hole in the insulating layer 352.

The sensor metal TSM and the bridge metal BRG can be disposed so as not to overlap with the light emitting device ED, but the embodiments of the present disclosure are not limited thereto. The sensor metal TSM and the bridge metal BRG can overlap with the bank 333, but the embodiments of the present disclosure are not limited thereto.

A plurality of sensor metals TSM can form one touch electrode TE, and can be disposed in a mesh form and electrically connected with each other. A portion of the sensor metal TSM and another portion of the sensor metal TSM can be electrically connected through the bridge metal BRG to form one touch electrode TE.

The protective layer 353 can be disposed on the sensor metal TSM and the bridge metal BRG. The protective layer 353 can be disposed while covering the sensor metal TSM and the bridge metal BRG.

A touch line TL can electrically connect the touch electrode TE and the touch pad TP. The touch line TL can be composed of at least one of the sensor metal TSM and the bridge metal BRG, or can be composed of a separate metal layer, but the embodiments of the present disclosure are not limited thereto.

In the case that the display panel 110 is a type incorporating a touch sensor, the touch line TL can extend along a outer slope SLP ENCAP of the encapsulation layer 200, and can extend beyond the upper portion of the dam DAM to the touch pad TP in the non-active area NA.

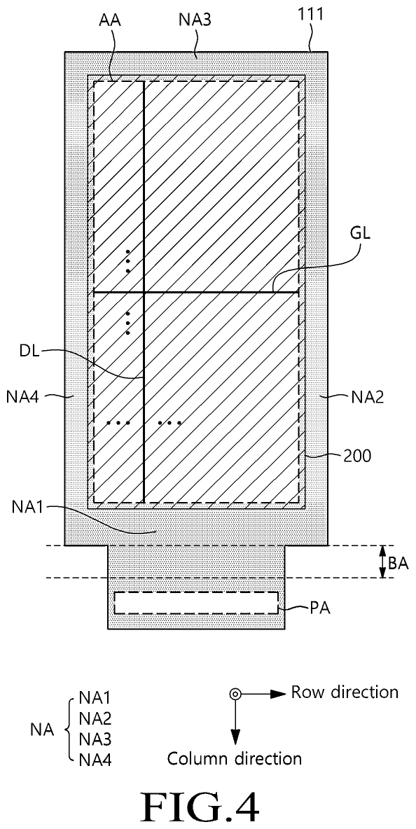

FIG. 4 illustrates a substrate of a display panel according to example embodiments of the present disclosure.

Referring to FIG. 4, the substrate 111 of the display panel 110 according to the example embodiments of the present disclosure can include an active area AA on which an image can be displayed and a non-active area NA on which an image may not be displayed.

The non-active area NA can include a first non-active area NA1, a second non-active area NA2, a third non-active area NA3, and a fourth non-active area NA4.

The first non-active area NA1 can be located in a column direction from the active area AA. The second non-active area NA2 can be located in a row direction from the active area AA. The third non-active area NA3 can be located in a column direction from the active area AA but can be located on the opposite side of the first non-active area NA1. The fourth non-active area NA4 can be located in the row direction from the active area AA but can be located on the opposite side of the second non-active area NA2.

For example, the column direction can be the direction in which the data line DL is extended, and the row direction can be the direction in which the gate line GL is extended. For another example, the column direction can be the direction in which the gate line GL is extended, and the row direction can be the direction in which the data line DL is extended. The column direction and the row direction can be relative directions. For example, the column direction can be a row direction depending on the viewing point, and the row direction can be a column direction depending on the viewing point. In the following, for the convenience of explanation, it is exemplified that each of the plurality of data lines DL is arranged in the column direction, and each of the plurality of gate lines GL is arranged in the row direction, but the embodiments of the present disclosure are not limited thereto.

The first non-active area NA1 can include a pad area PA. There can be disposed a plurality of pads to which at least one driving circuit or printed circuit board is electrically connected in the pad area PA. For example, a plurality of data lines DL, driving voltage lines VDDL, and base voltage lines VSSL can be electrically connected to the plurality of pads, but the embodiments of the present disclosure are not limited thereto. As an example, the pad area PA can be additionally or alternatively included in the third non-active area NA3, without being limited thereto.

The first non-active area NA1 can further include a bending area BA. In this case, the substrate 111 can be a flexible substrate. For another example, the first non-active area NA1 may not include a bending area BA.

The display panel 110 can further include a ground line disposed in the non-active area NA of the substrate 111. The ground line can be disposed from one point of the pad area PA to another point of the pad area PA via the second non-active area NA2, the third non-active area NA3, and the fourth non-active area NA4, but the embodiments of the present disclosure are not limited thereto.

In the display panel 110 according to the example embodiments of the present disclosure, the encapsulation layer 200 can have a structure in which an inorganic film and an organic film are laminated, but the embodiments of the present disclosure are not limited thereto. In this case, as an example, an edge of the encapsulation layer 200 can be an edge of the organic film. The encapsulation layer 200 can extend or expand from the active area AA to a part of the non-active area NA.

The display panel 110 according to the example embodiments of the present disclosure can include at least one dam or at least one stopper positioned further outside the organic film included in the encapsulation layer 200 to reduce or prevent overflow of the organic film included in the encapsulation layer 200. The at least one dam or the at least one stopper can include an organic film, and/or an inorganic film, but the embodiments of the present disclosure are not limited thereto.

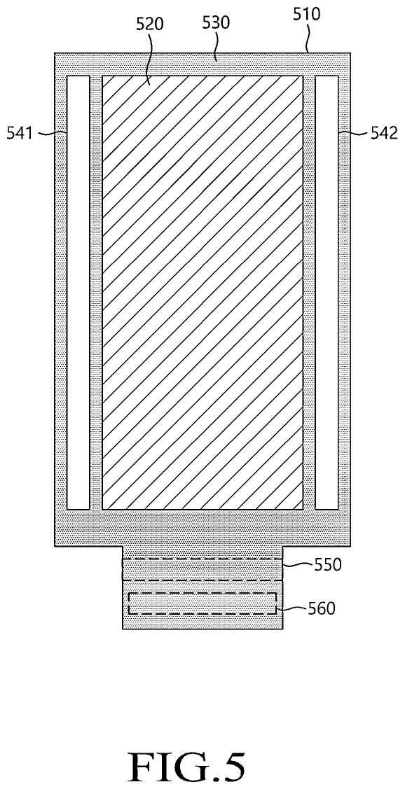

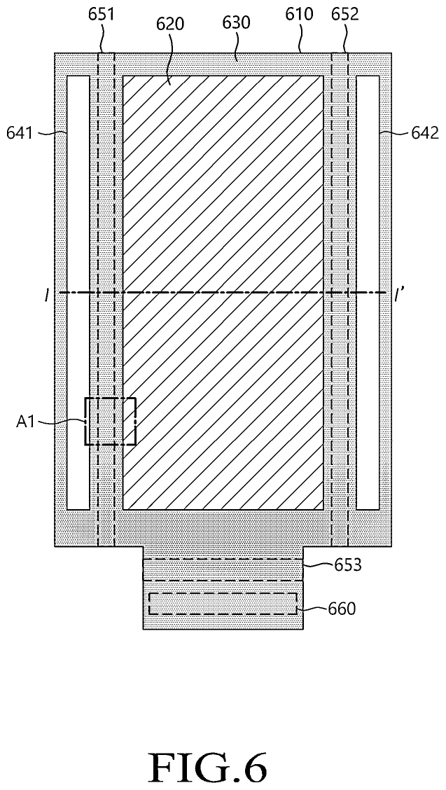

FIG. 5 and FIG. 6 illustrate a substrate on which a gate driving circuit according to example embodiments of the present disclosure is disposed.

Referring to an example of FIG. 5, the substrate can include an active area 520 and a non-active area 530.

The non-active area 530 can include a pad area 560 and a bending area 550.

When viewed from the plan view, the pad area 560 can be an area at the lower end of the substrate 510.

The bending area 550 can be an area at the lower portion of the active area 520. The bending area 550 can be an area between the pad area 560 and the active area 520.

A first gate driving circuit 541 can be disposed on the left side of the active area 520, but the embodiments of the present disclosure are not limited thereto.

A second gate driving circuit 542 can be disposed on the right side of the active area 520, but the embodiments of the present disclosure are not limited thereto. At least one of the first gate driving circuit 541 and the second gate driving circuit 542 can be omitted depending on the design.

The bending area 550 can be a bendable region. Since the bending area 550 can be bendable, the pad area 560 can be at least partially or fully disposed on a rear surface of the substrate 510. In this case, when viewed from the plan view, the area of the non-active area 530 can be reduced or minimized.

Referring to another example of FIG. 6, the substrate 610 can include one or more bendable areas, but the embodiments of the present disclosure are not limited thereto.

The substrate 610 can include a first bending area 651, a second bending area 652, and a third bending area 653, without being limited thereto.

The first bending area 651 can be a region between an area where the first gate driving circuit 641 is disposed and the active area 620.

The second bending area 652 can be an area between a region where the second gate driving circuit 642 is disposed and the active area 620.

The third bending area 653 can be a region between the pad area 660 and the active area 620.

The first bending area 651 can be an area which can be bent. Since the first bending area 651 can be bent, the first gate driving circuit 641 can be at least partially or fully located on the rear surface of the substrate 610.

The second bending area 652 can be an area which can be bent. Since the second bending area 652 can be bent, the second gate driving circuit 642 can be at least partially or fully located on the rear or back surface of the substrate 610.

Since the gate driving circuits 641 and 642 can be disposed on the rear surface of the substrate 610, the size of the bezel area of the display device 100 can be reduced or minimized.

As the size of the gate driving circuits 641 and 642 decreases, the bezel area can be reduced. Therefore, the gate driving circuits 641 and 642 is required to be designed small to reduce the bezel area. Since the gate driving circuits 641 and 642 are disposed on the rear surface of the substrate 610, the gate driving circuits 641 and 642 can be freely designed. For example, the transistors included in the gate driving circuits 641 and 642 can be designed to be relatively large, thereby improving the driving speed and/or signal delay of the gate driving circuits 641 and 642. For example, the driving performance and/or driving stability of the gate driving circuits 641 and 642 can be improved.

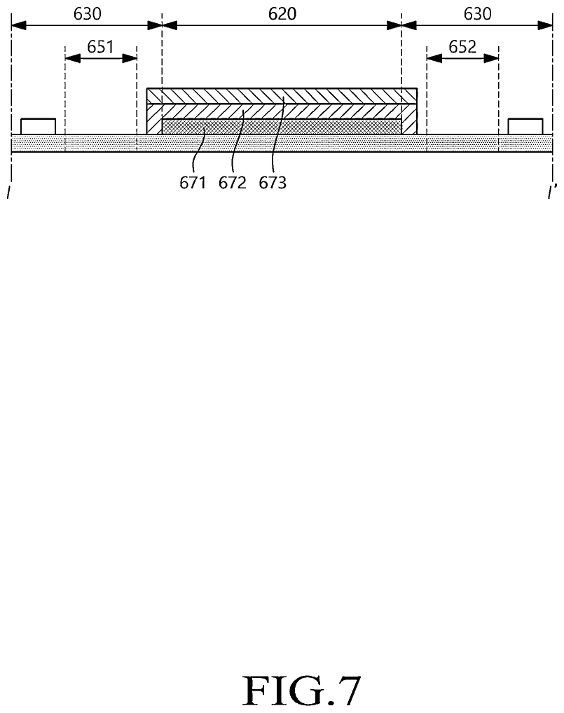

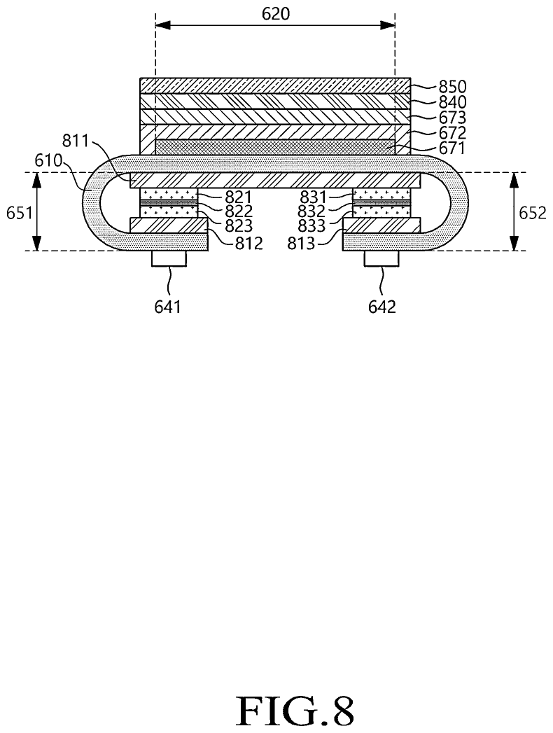

FIG. 7 is a cross-sectional view along line I-I′ of FIG. 6. FIG. 8 is a cross-sectional view of a portion of the substrate illustrated in FIG. 6.

Referring to FIG. 7, an image display layer 671 can be disposed on the substrate 610. The image display layer 671 can be disposed in an area corresponding to the active area 620.

An encapsulation layer 672 can be disposed on the image display layer 671. The encapsulation layer 672 can be disposed to cover the image display layer 671. The encapsulation layer 672 illustrated in FIG. 7 can be identical to or substantially identical to the encapsulation layer 200 illustrated in FIG. 3.

A touch sensor layer 673 can be disposed on the encapsulation layer 672. The touch sensor layer 673 illustrated in FIG. 7 can be identical to or substantially identical to the touch sensor layer 210 illustrated in FIG. 3.

A first gate driving circuit 641 can be disposed in the non-active area 630.

The non-active area 630 can include a first bending area 651.

The first bending area 651 can be an area between an area where the first gate driving circuit 641 is disposed and an area where the image display layer 671 is disposed.

The second gate driving circuit 642 can be disposed in the non-active area 630.

The non-active area 630 can include a second bending area 652.

The second bending area 652 can be an area between the region where the second gate driving circuit 642 is disposed and the region where the image display layer 671 is disposed.

The encapsulation layer 672 can be disposed in a part of the non-active area 630 and the active area 620.

In the active area 620, the encapsulation layer 672 can include an inorganic layer, an organic layer, and an inorganic layer that are sequentially stacked, but the embodiments of the present disclosure are not limited thereto. In the non-active area 630, the encapsulation layer 672 can include an inorganic layer and an inorganic layer that are sequentially stacked, but the embodiments of the present disclosure are not limited thereto.

The encapsulation layer 672 can be disposed in a part of the non-active area 630 adjacent to the active area 620, and may not be disposed in the first bending area 651. The encapsulation layer 672 can be disposed in a part of the non-active area 630 adjacent to the active area 620, and may not be disposed in the second bending area 652. For example, the inorganic layer and the organic layer may not be disposed in the first bending area 651 and the second bending area 652.

As an example, after the inorganic layer is formed or deposited on the entire surface of the bending areas 650, the inorganic layer corresponding to the bending areas 650 can be etched and removed. Accordingly, a portion of the inorganic layer can remain in a part of the non-active area 630 other than the bending areas 650. Embodiments are not limited thereto. As an example, the inorganic layer can be not formed or deposited in the bending areas 650, without any further etching process.

Since the encapsulation layer 672 is not disposed in the first bending area 651 and the second bending area 652, the first bending area 651 and the second bending area 652 can be easily bent. Since the first bending area 651 and the second bending area 652 are regions where the substrate 610 and the wirings are disposed, the first bending area 651 and the second bending area 652 can be easily bent.

Referring to FIG. 8, there are illustrated a first bending area 651 in a bent state and a second bending area 652 in a bent state.

A first support layer 811, a second support layer 812, a third support layer 813 can be disposed on a rear surface or a back surface of the substrate 610.

The first support layer 811 can be disposed in the active area 620. As an example, the first support layer 811 can have a width greater than or equal to that of the active area 620, without being limited thereto. As an example, the first support layer 811 can overlap the entirety of the active area 620, without being limited thereto.

The second support layer 812 can be disposed to overlap with the first gate driving circuit 641. The first gate driving circuit 641 can be disposed on the substrate 610. The second support layer 812 can be disposed on the rear surface of the substrate 610. As an example, the second support layer 812 can have a width greater than or equal to that of the first gate driving circuit 641, without being limited thereto. As an example, the second support layer 812 can overlap the entirety of the first gate driving circuit 641, without being limited thereto.

The third support layer 813 can be disposed to overlap with the second gate driving circuit 642. The second gate driving circuit 642 can be disposed on the substrate 610. The third support layer 813 can be disposed on the rear surface of the substrate 610. As an example, the third support layer 813 can have a width greater than or equal to that of the second gate driving circuit 642, without being limited thereto. As an example, the third support layer 813 can overlap the entirety of the second gate driving circuit 642, without being limited thereto.

The first adhesive layers 821, 822 and 823 can be disposed between the first support layer 811 and the second support layer 812.

Since the first adhesive layers 821, 822 and 823 are disposed to contact the first support layer 811 and the second support layer 812, the first adhesive layers 821, 822 and 823 can connect or fix the first support layer 811 and the second support layer 812.

As the first adhesive layer 821, 822 and 823 connects or fixes the first support layer 811 and the second support layer 812), the first bending area 651 can be maintained in a bent state.

The first adhesive layer 821, 822 and 823 can include a first adhesive 821, a second adhesive 822, and a third adhesive 823, without being limited thereto. As an example, the first adhesive layer can include only one or two of the first adhesive 821, the second adhesive 822, and the third adhesive 823 or more than three adhesives.

The first adhesive 821 can be disposed on the first support layer 811. The first adhesive 821 can be disposed in contact with the first support layer 811. The first adhesive 821 can be a pressure-sensitive adhesive, but is not limited thereto.

The second adhesive 822 can be disposed between the first adhesive 821 and the third adhesive 823. The second adhesive 822 can be composed of a different material from the first adhesive 821 and the third adhesive 823, but is not limited thereto. For example, the second adhesive 822 can be a double-sided tape, a foam tape, or a double-sided foam tape, but is not limited thereto.

The third adhesive 823 can be disposed on the second support layer 812. The third adhesive 823 can be disposed in contact with the second support layer 812. The third adhesive 823 can be a pressure-sensitive adhesive, but is not limited thereto. The third adhesive 823 can be composed of the same material as the first adhesive 821, but is not limited thereto.

The second adhesive layers 831, 832 and 833 can be disposed between the first support layer 811 and the third support layer 813.

Since the second adhesive layers 831, 832 and 833 are disposed in contact with the first support layer 811 and the third support layer 813, the second adhesive layers 831, 832 and 833 can connect or fix the first support layer 811 and the third support layer 813.

Since the second adhesive layers 831, 832 and 833 connect or fix the first support layer 811 and the third support layer 813, the second bending area 652 can be maintained in a bent state.

The second adhesive layers 831, 832 and 833 can include the fourth adhesive 831, the fifth adhesive 832, and the sixth adhesive 833, without being limited thereto.

The fourth adhesive 831 can be disposed on the first support layer 811. The fourth adhesive 831 can be disposed in contact with the first support layer 811. The fourth adhesive 831 can be a pressure-sensitive adhesive, but is not limited thereto.

The fifth adhesive 832 can be disposed between the fourth adhesive 831 and the sixth adhesive 833. The fifth adhesive 832 can be composed of a different material from the fourth adhesive 831 and the sixth adhesive 833, but is not limited thereto. For example, the fifth adhesive 832 can be a double-sided tape, a foam tape, or a double-sided foam tape, but is not limited thereto.

The sixth adhesive 833 can be disposed on the third support layer 813. The sixth adhesive 833 can be disposed in contact with the third support layer 813. The sixth adhesive 833 can be a pressure-sensitive adhesive, but is not limited thereto. The sixth adhesive 833 can be composed of the same material as the fourth adhesive 831, but is not limited thereto.

A polarizing layer 840 can be disposed on the touch sensor layer 673. The polarizing layer 840 can reduce or prevent external light from being reflected to the user. As another example, the display device 100 may not include the polarizing layer 840.

A cover glass 850 can be disposed on the polarizing layer 840. The cover glass 850 can protect layers disposed under the cover glass 850. As another example, the cover glass 850 can be formed of a material other than glass, or can be omitted depending on the design.

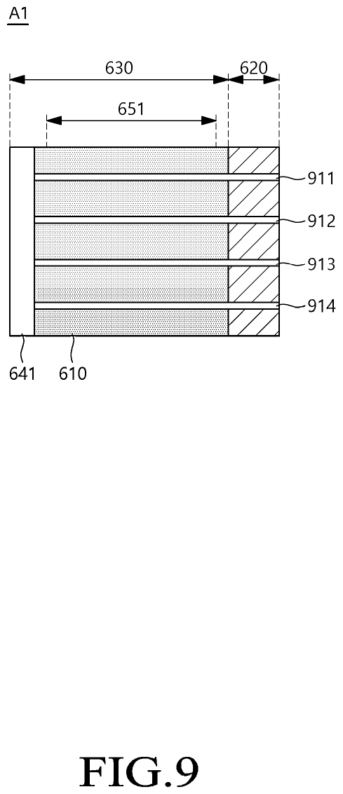

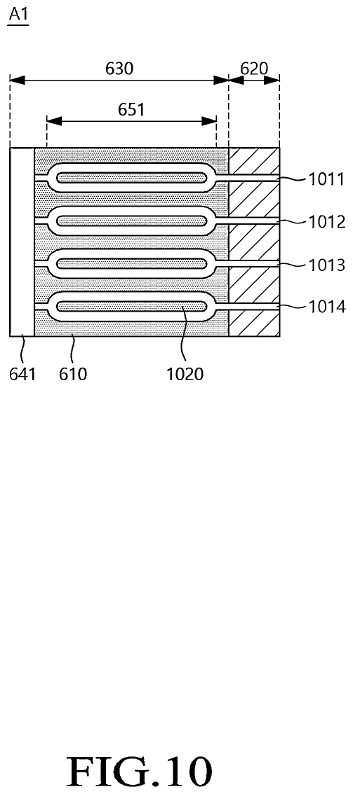

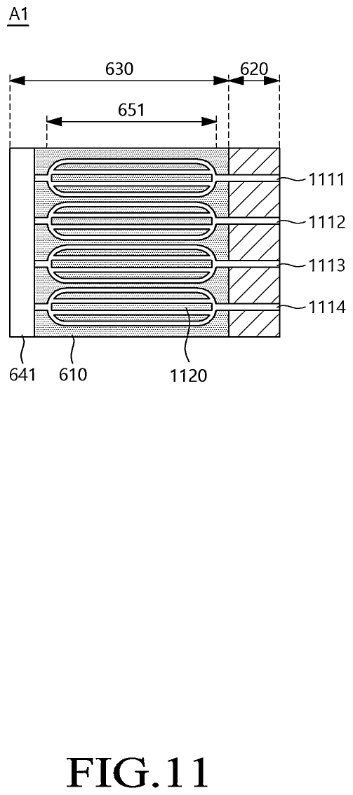

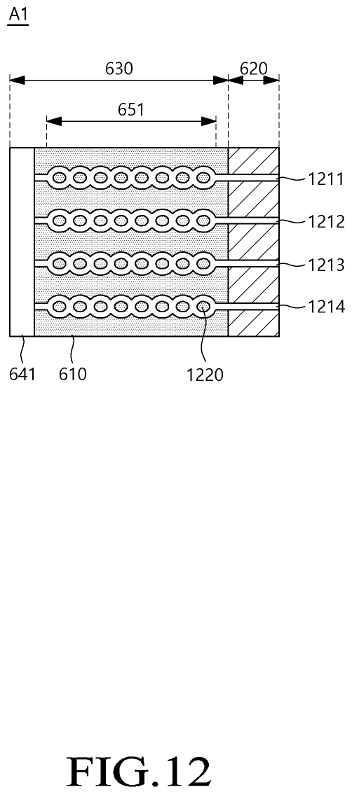

FIG. 9, FIG. 10, FIG. 11, and FIG. 12 illustrate an area A1 of FIG. 6 according to various examples of the present disclosure.

Referring to an example of FIG. 9, the first gate driving circuit 641 can be electrically connected to a plurality of gate lines 911, 912, 913 and 914.

The plurality of gate lines 911, 912, 913 and 914 can be disposed in the active area 620 and the non-active area 630.

The plurality of gate lines 911, 912, 913 and 914 can be disposed in the first bending area 651.

The plurality of gate lines 911, 912, 913 and 914 can be in a straight line shape, but the embodiments of the present disclosure are not limited thereto. The plurality of gate lines 911, 912, 913 and 914 can be disposed to extend from the non-active area 630 to the active area 620.

The plurality of gate lines 911, 912, 913 and 914 can be electrically connected to the first gate driving circuit 641. The plurality of gate lines 911, 912, 913 and 914 can be disposed to pass through the first bending area 651. Although it is illustrated only four gate lines, embodiments are not limited thereto. As an example, there could be less than four gate lines or five or more gate lines. Although it is illustrated that the four gate lines can have the same shape, embodiments are not limited thereto. As an example, at least one of the four gate lines can have a shape different from those of the other gate lines.

Referring to another example of FIG. 10, at least one or each of the plurality of gate lines 1011, 1012, 1013 and 1014 can include one hole 1020.

The first gate line 1011 can include one hole 1020 in the first bending area 651. For example, the first gate line 1011 can include one or more holes 1020 arranged in an area corresponding to the first bending area 651. One hole 1020 can have a circular shape, or an elliptical shape or an oval shape, for example, extending left and right, but the embodiments of the present disclosure are not limited thereto. In the portion connected to the first gate driving circuit 641, the first gate line 1011 can have a single wiring form, but the embodiments of the present disclosure are not limited thereto. In the first bending area 651, the first gate line 1011 can have two wiring forms, but the embodiments of the present disclosure are not limited thereto. In the active area 620, the first gate line 1011 can have a single wiring form, but the embodiments of the present disclosure are not limited thereto.

One hole 1020 can have a redundancy structure. The first gate line 1011 corresponding to the first bending area 651 can be in the form of two wirings, and the same signal can be supplied to the two wirings simultaneously, but the embodiments of the present disclosure are not limited thereto. Each of the remaining gate lines 1012, 1013 and 1014 can include one hole 1020, but the embodiments of the present disclosure are not limited thereto.

Referring to another example of FIG. 11, at least one or each of the plurality of gate lines 1111, 1112, 1113 and 1114 can include three holes 1120. As an example, each of the plurality of gate lines 1111, 1112, 1113 and 1114 can include three holes 1120 arranged in a vertical direction, without being limited thereto. As an example, the three holes 1120 can have the same size or different sizes.

The first gate line 1111 can include three holes 1120 in the first bending area 651. For example, the first gate line 1011 can include one or more holes 1120 arranged in an area corresponding to the first bending area 651. The three holes 1120 can be in an oval shape or an elliptical shape extending left and right, but the embodiments of the present disclosure are not limited thereto. In the portion connected to the first gate driving circuit 641, the first gate line 1111 can be in a single wiring form, but the embodiments of the present disclosure are not limited thereto. In the first bending area 651, the first gate line 1111 can be in a four wiring form, but the embodiments of the present disclosure are not limited thereto. In the active area 620, the first gate line 1111 can be in a single wiring form, but the embodiments of the present disclosure are not limited thereto.

The three holes 1120 can be in a redundancy structure. The first gate line 1111 corresponding to the first bending area 651 can have four wiring forms, and the same signal can be supplied to the four wirings simultaneously, but the embodiments of the present disclosure are not limited thereto. Each of the remaining gate lines 1112, 1113 and 1114 can include three holes 1120, but the embodiments of the present disclosure are not limited thereto.

Referring to another example of FIG. 12, at least one or each of the plurality of gate lines 1211, 1212, 1213 and 1214 can include a plurality of holes 1220. As an example, at each of the plurality of gate lines 1211, 1212, 1213 and 1214 can include a plurality of holes 1220 arranged in a horizontal direction, without being limited thereto. As an example, the plurality of holes 1220 arranged in a horizontal direction can have the same shape and size or different shapes and sizes.

The first gate line 1211 can include a plurality of holes 1220 in the first bending area 651. For example, the first gate line 1011 can include one or more holes 1220 arranged in an area corresponding to the first bending area 651. Each of the plurality of holes 1220 can have a circular shape, an elliptical shape or an oval shape, for example, extending in any directions, but the embodiments of the present disclosure are not limited thereto. The plurality of holes 1220 can have a shape in which a plurality of circular rings are combined, but the embodiments of the present disclosure are not limited thereto. As an example, the plurality of circular rings can be separated from each other, with a straight line shape interposed therebetween. However, the hole 1220 being circular is an example, and the hole 1220 can be configured in various shapes such as a triangle, a square, a rhombus, etc.

In a portion connected to the first gate driving circuit 641, the first gate line 1211 can have a single wiring shape, but the embodiments of the present disclosure are not limited thereto. In the first bending area 651, the first gate line 1211 can have a shape in which a plurality of circular shapes are connected, but the embodiments of the present disclosure are not limited thereto. In the active area 620, the first gate line 1211 can be a single wiring type, but the embodiments of the present disclosure are not limited thereto.

The plurality of holes 1220 can be a redundancy structure. Each of the remaining gate lines 1212, 1213 and 1214 can include a plurality of holes 1220, but the embodiments of the present disclosure are not limited thereto.

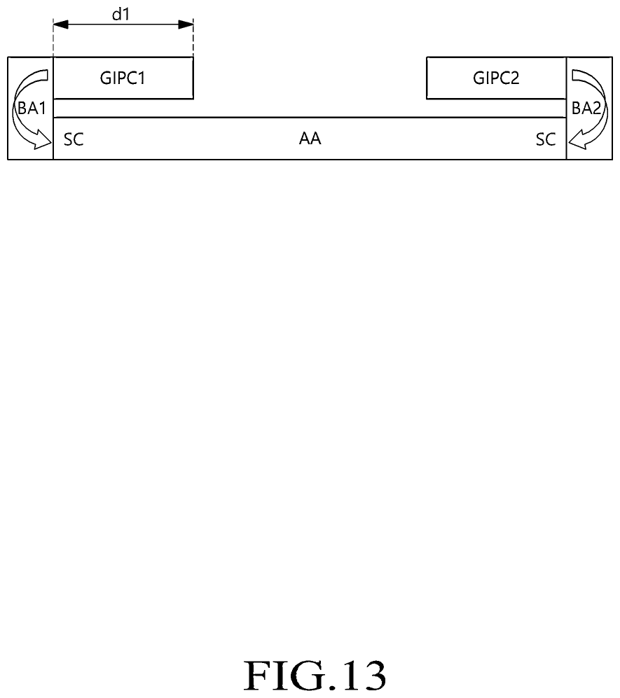

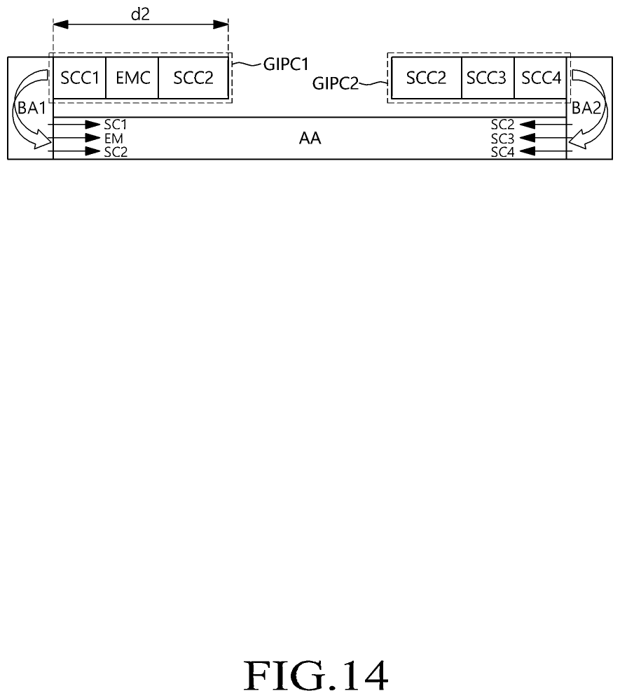

FIG. 13 and FIG. 14 illustrate signals output from a gate driving circuit according to example embodiments of the present disclosure.

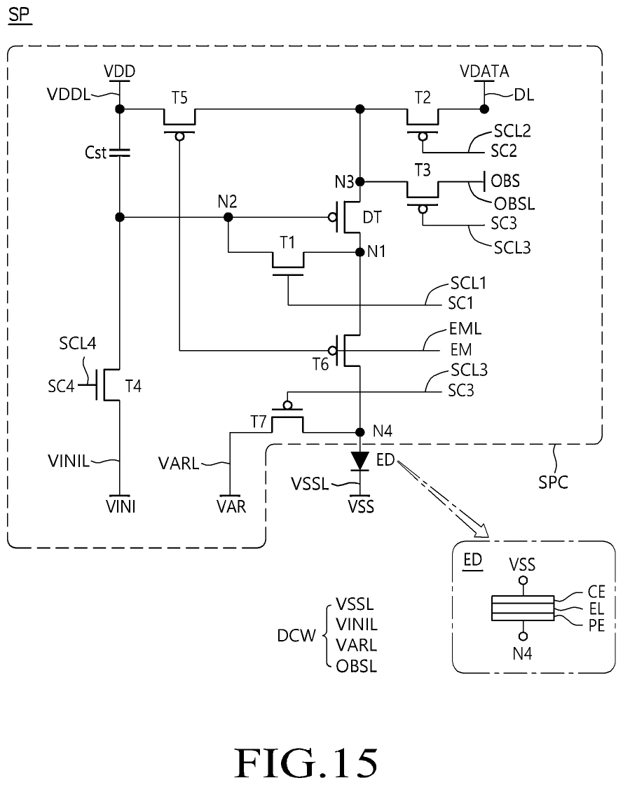

FIG. 15 illustrates an equivalent circuit of a subpixel of a display panel according to example embodiments of the present disclosure.

Referring to FIG. 13, a first gate driving circuit GIPC1 and a second gate driving circuit GIPC2 can output a scan signal SC.

The scan signal SC can be supplied to a plurality of subpixels disposed in the active area AA through the bending areas BA1 and BA2.

Since no encapsulation layer is disposed in the bending areas BA1 and BA2, the bending areas BAL and BA2 can be easily bent.

Since the gate driving circuits GIPC1 and GIPC2 are disposed on the rear surface of the substrate, the design of the gate driving circuits GIPC1 and GIPC2 can be relatively free. Transistors included in the gate driving circuits GIPC1 and GIPC2 can be designed to be relatively large, thereby improving the driving speed and/or signal delay of the gate driving circuits GIPC1 and GIPC2. For example, it is possible to improve the driving performance and/or driving stability of the gate driving circuits GIPC1 and GIPC2.

Referring to FIG. 14, the first gate driving circuit GIPC1 can include a first scan signal driving circuit SCC1, a second scan signal driving circuit SCC2, and an emission control signal driving circuit EMC, without being limited thereto. The second gate driving circuit GIPC2 can include a second scan signal driving circuit SCC2, a third scan signal driving circuit SCC3, and a fourth scan signal driving circuit SCC4, without being limited thereto. The first scan signal driving circuit SCC1, the second scan signal driving circuit SCC2, the emission control signal driving circuit EMC, the second scan signal driving circuit SCC2, the third scan signal driving circuit SCC3, and the fourth scan signal driving circuit SCC4 could be distributed in the first gate driving circuit GIPC1 and the second gate driving circuit GIPC2 in various ways. As an example, at least one of the above-mentioned components can be omitted depending on the design. In particular, as an example, one of the first gate driving circuit GIPC1 and the second gate driving circuit GIPC2 can be omitted depending on the design. As an example, a crack detection circuit can be further disposed on the rear surface of the substrate. The crack detection circuit can be disposed adjacent to the gate driving circuit GIP1 and GIP2, without being limited thereto.

For example, a left-right width d2 of the gate driving circuits GIPC1 and GIPC2 illustrated in FIG. 14 can be larger than a left-right width d1 of the gate driving circuits GIPC1 and GIPC2 illustrated in FIG. 13. As an example, the left-right width of the gate driving circuits GIPC1 and GIPC2 can be the same or can be different from each other.

The first scan signal driving circuit SCC1 of the first gate driving circuit GIPC1 can output a first scan signal SC1.

The second scan signal driving circuit SCC2 of the first gate driving circuit GIPC1 can output a second scan signal SC2.

The emission control signal driving circuit EMC of the first gate driving circuit GIPC1 can output an emission control signal EM.

The second scan signal driving circuit SCC2 of the second gate driving circuit GIPC2 can output the second scan signal SC2.

The third scan signal driving circuit SCC3 of the second gate driving circuit GIPC2 can output a third scan signal SC3.

The fourth scan signal driving circuit SCC4 of the second gate driving circuit GIPC2 can output a fourth scan signal SC4.

The scan signals SC and the emission control signal EM can be supplied to a plurality of subpixels disposed in the active area AA.

FIG. 15 illustrates an equivalent circuit of a subpixel in a display panel according to example embodiments of the present disclosure.

Referring to FIG. 15, each of a plurality of subpixels SP disposed in the display panel 110 according to example embodiments of the present disclosure can include a light emitting device ED and a subpixel circuit SPC.

The subpixel circuit SPC can include a driving transistor DT and a capacitor Cst.

The subpixel SP can include a light emitting device ED and a subpixel circuit SPC for driving the light emitting device ED. The subpixel circuit SPC can include eight transistors DT and T1˜T7 and one storage capacitor Cst, but the embodiments of the present disclosure are not limited thereto. The subpixel circuit SPC can include a first node N1, a second node N2, a third node N3, and a fourth node N4, but the embodiments of the present disclosure are not limited thereto.

The light emitting device ED can include a pixel electrode PE, an intermediate layer EL, and a common electrode CE. The pixel electrode PE can be electrically connected to the fourth node N4. The common electrode CE can be electrically connected to a base voltage line VSSL to which a base voltage VSS is applied. The light emitting device ED can be connected between the fourth node N4 and the base voltage line VSSL.

The driving transistor DT can include a source node, a drain node, and a gate node. The drain node or the source node of the driving transistor DT can be electrically connected to the first node N1, the gate node of the driving transistor DT can be electrically connected to the second node N2, and the source node or the drain node of the driving transistor DT can be electrically connected to a third node N3. The driving transistor DT can be connected to the first node N1 and the third node N3.

A first transistor T1 can be turned on and off by the first scan signal SC1 supplied from the first scan signal line SLC1, and can control the connection between the first node N1 and the second node N2. The first transistor T1 can be connected between the first node N1 and the second node N2.

A second transistor T2 can be turned on and off by the second scan signal SC2 supplied from the second scan signal line SCL2, and can control the connection between the third node N3 and the data line DL to which the data voltage VDATA is applied.

A third transistor T3 can be turned on and off by the third scan signal SC3 supplied from the third scan signal line SCL3, and can control the connection between the third node N3 and a bias voltage line OBSL to which a bias voltage OBS is applied.

A fourth transistor T4 can be turned on and off by the fourth scan signal SC4 supplied from the fourth scan signal line SCL4, and can control the connection between the second node N2 and an initialization voltage line VINIL to which an initialization voltage VINI is applied.

A fifth transistor T5 can be turned on and off by the emission control signal EM supplied from the emission control signal line EML, and can control the connection between the third node N3 and the driving voltage line VDDL to which the driving voltage VDD is applied.

A sixth transistor T6 can be turned on and off by the emission control signal EM supplied from the emission control signal line EML, and can control the connection between the first node N1 and the fourth node N4.

A seventh transistor T7 can be turned on and off by the third scan signal SC3 supplied from the third scan signal line SCL3, and can control the connection between the fourth node N4 and a reset voltage line VARL to which a reset voltage VAR is applied.

The storage capacitor Cst can be connected between the driving voltage line VDDL and the second node N2.

Each of the eight transistors DT and T1˜T7 can be an n-type transistor turned on by a high-level gate voltage or a p-type transistor turned on by a low-level gate voltage. For example, the driving transistor DT, the second transistor T2, the third transistor T3, the fifth transistor T5, the sixth transistor T6, and the seventh transistor T7 can be p-type transistors, and the first transistor T1 and the fourth transistor T4 can be n-type transistors. However, the embodiments of the present disclosure are not limited thereto, and can be variously modified. For example, the driving transistor DT and one of the first to seventh transistors T1 to T7 can be composed of one of a combination of an oxide semiconductor layer and a low-temperature polysilicon semiconductor layer, but the embodiments of the present disclosure are not limited thereto.

A direct current (DC) signal applied to the subpixel SP can include a base voltage VSS.

The DC signal applied to the subpixel SP can further include at least one of an initialization voltage VINI, a reset voltage VAR, and a bias voltage OBS, but the embodiments of the present disclosure are not limited thereto. The DC signal applied to the subpixel SP can further include a driving voltage VDD.

According to the example embodiments of the present disclosure, the DC signal applied to the subpixel SP can be a signal having a constant voltage level, and can also be referred to as a power supply voltage. A signal wiring for transmitting the DC signal to the subpixel SP can be referred to as a DC signal wiring DCW.

The DC signal wiring DCW according to the example embodiments of the present disclosure can include a base voltage line VSSL. The DC signal wiring DCW according to the example embodiments of the present disclosure can further include at least one of a base voltage line VSSL, an initialization voltage line VINIL, a reset voltage line VARL, and a bias voltage line OBSL. The DC signal wiring DCW according to example embodiments of the present disclosure can further include a driving voltage line VDDL.

Embodiments of the present disclosure described above are briefly described as follows.

A display device according to example embodiments of the present disclosure can include a substrate including an active area and a non-active area, and a first gate driving circuit disposed on the substrate. The non-active area can include a first bending area between the active area and an area where the first gate driving circuit is disposed.

The display device according to example embodiments of the present disclosure can further include a first support layer disposed on a rear surface of the substrate, a second support layer disposed on the rear surface of the substrate and overlapping with the first gate driving circuit, and a first adhesive layer disposed on the first support layer and the second support layer.

According to example embodiments of the present disclosure, the first adhesive layer can include a first adhesive disposed on the first support layer, a second adhesive disposed on the second support layer, and a third adhesive disposed between the first adhesive and the second adhesive, and including a material different from the first adhesive and the second adhesive.

The display device according to example embodiments of the present disclosure can further include a second gate driving circuit disposed on the substrate. The non-active area can further include a second bending area between the active area and an area where the second gate driving circuit is disposed.

The display device according to example embodiments of the present disclosure can further include a third support layer disposed on the rear surface of the substrate and overlapping with the second gate driving circuit, and a second adhesive layer disposed on the first support layer and the third support layer. The second adhesive layer can include a third adhesive disposed on the first support layer, a fourth adhesive disposed on the second support layer, and a fifth adhesive disposed between the third adhesive and the fourth adhesive, and including a material different from the third adhesive and the fourth adhesive.

According to example embodiments of the present disclosure, the non-active area can include a pad area, and a third bending area between the pad area and the active area.

The display device according to example embodiments of the present disclosure can further include an image display layer disposed on the substrate, an encapsulation layer disposed on the image display layer, and a touch unit disposed on the encapsulation layer. The first gate driving circuit can be disposed to overlap with the image display layer on a rear surface of the substrate.

According to example embodiments of the present disclosure, the first bending area can be bent, and a portion of the substrate can be bent toward a rear surface of the substrate.

According to example embodiments of the present disclosure, the encapsulation layer can be disposed in a part of the non-active area, and can be not disposed in the first bending area.

The display device according to example embodiments of the present disclosure can further include a first gate line electrically connected to the first gate driving circuit and disposed to pass through the first bending area.

According to example embodiments of the present disclosure, the first gate line can include one or more holes disposed in an area corresponding to the first bending area.

According to example embodiments of the present disclosure, the one or more holes can have an oval shape.

According to example embodiments of the present disclosure, the first gate driving circuit can output a scan signal to the first gate line.

According to example embodiments of the present disclosure, the image display layer can include a plurality of subpixels. Each of the plurality of subpixels can include a light emitting device, a driving transistor for driving the light emitting device, and a scan transistor disposed between a gate node of the driving transistor and a data line.

According to example embodiments of the present disclosure, one of a semiconductor layers of each of the driving transistor and the scan transistor can include one of oxide semiconductor, amorphous silicon, polysilicon, and low-temperature polysilicon.

According to example embodiments of the present disclosure, the image display layer can includes a plurality of subpixels. The first gate driving circuit can output an emission control signal to a second gate line, and the subpixels can be controlled by the scan signal and the emission control signal.

The display device according to various embodiments of the present disclosure can be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle navigation system, a vehicle display device, a vehicle device, a theater device, a theater display device, a television, a wallpaper device, a signage device, a game device, a notebook, a monitor, a camera, a camcorder, and home appliances.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate including an active area and a non-active area; and
a first gate driving circuit disposed in the non-active area on the substrate,
wherein the non-active area includes a first bending area between the active area and an area where the first gate driving circuit is disposed.

2. The display device of claim 1, further comprising:
a first support layer disposed on a rear surface of the substrate and overlapping with the active area;
a second support layer disposed on the rear surface of the substrate and overlapping with the first gate driving circuit; and
a first adhesive layer disposed on the first support layer and the second support layer.

3. The display device of claim 2, wherein the first adhesive layer comprises:
a first adhesive disposed on the first support layer;
a second adhesive disposed on the second support layer; and
a third adhesive disposed between the first adhesive and the second adhesive, and including a material different from the first adhesive and the second adhesive.

4. The display device of claim 3, wherein each of the first adhesive and the second adhesive includes a pressure-sensitive adhesive, and
wherein the third adhesive includes a double-sided tape, a foam tape, or a double-sided foam tape.

5. The display device of claim 3, further comprising:
a second gate driving circuit in the non-active area disposed on the substrate opposite to the first gate driving circuit,
wherein the non-active area further includes a second bending area between the active area and an area where the second gate driving circuit is disposed.

6. The display device of claim 5, further comprising:
a third support layer disposed on the rear surface of the substrate and overlapping with the second gate driving circuit; and
a second adhesive layer disposed on the first support layer and the third support layer,
wherein the second adhesive layer includes:
a third adhesive disposed on the first support layer;
a fourth adhesive disposed on the second support layer; and
a fifth adhesive disposed between the third adhesive and the fourth adhesive, and including a material different from the third adhesive and the fourth adhesive.

7. The display device of claim 5, wherein the non-active area includes:
a pad area; and
a third bending area between the pad area and the active area.

8. The display device of claim 2, wherein the first bending area is bent, and
wherein the first support layer and the second support layer overlap with each other with the first adhesive layer disposed therebetween.

9. The display device of claim 1, further comprising:
an image display layer disposed on the substrate,
wherein the first gate driving circuit is disposed to overlap with the image display layer on a rear surface of the substrate.

10. The display device of claim 9, wherein the first bending area is bent, and a portion of the substrate is bent toward the rear surface of the substrate.

11. The display device of claim 9, further comprising:
an encapsulation layer disposed on the image display layer,
wherein the encapsulation layer is disposed in a part of the non-active area, and is not disposed in the first bending area.

12. The display device of claim 1, further comprising:
a first gate line electrically connected to the first gate driving circuit and disposed to pass through the first bending area.

13. The display device of claim 12, wherein the first gate line includes one or more holes disposed in an area corresponding to the first bending area.

14. The display device of claim 13, wherein the one or more holes have an oval shape extending in a direction along which the first gate line extends.

15. The display device of claim 13, wherein when the holes are disposed, the holes are arranged in a direction crossing a direction along which the first gate line extends.

16. The display device of claim 13, wherein when the holes are disposed, the holes are arranged in a direction along which the first gate line extends.

17. The display device of claim 16, wherein the holes are configured in circular rings combined with each other.

18. The display device of claim 12, wherein the first gate line is configured in a single wiring form in a portion connected to the first gate driving circuit, in a multiple wiring form in the first bending area, and in a single wiring form in the active area.

19. The display device of claim 18, wherein a same signal is configured to be supplied to multiple wirings of the multiple wiring form simultaneously.

20. The display device of claim 12, wherein the first gate driving circuit outputs a scan signal to the first gate line.

21. The display device of claim 20, further comprising:
an image display layer disposed on the substrate,
wherein the image display layer includes a plurality of subpixels, and
wherein each of the plurality of subpixels includes:
a light emitting device;
a driving transistor configured to drive the light emitting device; and
a scan transistor disposed between a gate node of the driving transistor and a data line.

22. The display device of claim 21, wherein one of a semiconductor layers of each of the driving transistor and the scan transistor includes one of oxide semiconductor, amorphous silicon, and polysilicon.

23. The display device of claim 20, further comprising:
an image display layer disposed on the substrate,
wherein the image display layer includes a plurality of subpixels,
wherein the first gate driving circuit outputs an emission control signal to a second gate line, and
wherein the plurality of subpixels are controlled by the scan signal and the emission control signal.

24. A display device comprising:
a substrate including an active area and a non-active area;
a first gate driving circuit disposed in the non-active area on the substrate; and
a first gate line electrically connected to the first gate driving circuit and extending to the active area,
wherein the first gate line is configured in a single wiring form in a portion connected to the first gate driving circuit, in a multiple wiring form in an area between the active area and an area where the first gate driving circuit is disposed, and in a single wiring form in the active area.

25. The display device of claim 24, wherein the area between the active area and the area where the first gate driving circuit is disposed is bendable.
